(19) United States
(12) Patent Application Publication
(10) Pub. No.: US 2026/0186024 A1
(43) Pub. Date: Jul. 2, 2026

(54) MEMS PROBE CARD WITH UPPER AND LOWER STOPPERS

(71) Applicant: SDA CO., LTD, Gyeonggi-do (KR)

(72) Inventors: Chang Min IM, Gyeonggi-do (KR); Woong Kyum KIM, Gyeonggi-do (KR); Sang Bum SHIM, Gyeonggi-do (KR)

(21) Appl. No.: 19/254,701

(22) Filed: Jun. 30, 2025

(30) Foreign Application Priority Data
Dec. 26, 2024 (KR) 10-2024-0196583

(51) Int. Cl. G01R 1/073; G01R 1/067

(52) U.S. Cl. CPC G01R 1/07342; G01R 1/06716; G01R 1/06744; G01R 1/07357

(57) ABSTRACT

Proposed is a MEMS probe card with upper and lower stoppers including an upper guide plate having an upper via-hole formed therein, a lower guide plate having a lower via-hole formed therein, a probe whose upper part and lower part are respectively accommodated in the upper via-hole and the lower via-hole, an upper stopper provided to prevent vertical separation when the probe is inserted into the upper guide plate and the lower guide plate, and a lower stopper provided to prevent separation when the probe inserted into the each of the upper guide plate and the lower guide plate is pulled in the opposite direction of insertion.

### CROSS REFERENCE TO RELATED APPLICATION

The present application claims priority to Korean Patent Application No. 10-2024-0196583, filed Dec. 26, 2024, the entire contents of which is incorporated herein for all purposes by this reference.

### BACKGROUND

### Technical Field

The present disclosure relates to a MEMS probe card and, more particularly, to a MEMS probe card with upper and lower stoppers, the probe card allowing probes for testing electrical requirements of semiconductor devices to be inserted into via-holes of a plurality of guide plates.

### Description of the Related Art

Unless otherwise indicated herein, the contents described in this section are not prior art to the claims of this application and their inclusion in this section is not intended to be considered prior art.

In general, semiconductor devices are manufactured through a fabrication process that involves creating circuit patterns and contact pads for inspection on a silicon wafer, and an assembly process that transforms individual semiconductor chips into functional products from the wafer on which the circuit patterns and contact pads are created.

Between the fabrication process and the assembly process, an electrical die sorting (EDS) process, which is an inspection process, is performed to inspect the electrical characteristics of the wafer by applying an electrical signal to the contact pads created on the wafer.

The EDS process described above is a process performed to determine whether the semiconductor devices fabricated on the wafer have reached the desired quality level (by inspecting for defects) so that a portion of the wafer where a defect occurred is eliminated during the assembly process.

That is, inspection at the wafer level is to inspect the electrical operation status of each chip at the wafer level before cutting or dicing a semiconductor wafer imprinted with of hundreds to thousands of semiconductor chips into individual chips and proceeding with the assembly process, thereby filtering out chip defects at the wafer level in advance, thereby enabling cost reduction at the subsequent packaging stage.

A probe station, which applies electrical signals to semiconductor devices on a wafer and analyzes the resulting electrical responses to identify defective chips, is mainly used in the EDS process.

The probe station is a device designed to measure the electrical characteristics of semiconductor devices by connecting semiconductor devices to automated test equipment (ATE). At this time, a probe card is installed to transmit electrical signals to the pads of the semiconductor devices during testing.

Probe cards are categorized into vertical, cantilever, and MEMS (micro-electro mechanical system) types based on the mechanical operation principle of the contact terminal thereof.

MEMS type probe cards are manufactured by creating cantilever-shaped probes on a substrate in a batch process and then bonding the probes to a separate substrate. These MEMS type probe cards have the advantage of high mechanical reliability and excellent electrical performance. On the other hand, the miniaturization of semiconductor devices, driven by the need for higher integration, has led to smaller connection terminals and narrower contact pitches, limiting the improvement of contact characteristics and making it difficult to detect and characterize these narrow areas.

A conventional MEMS type probe card for testing semiconductor devices illustrated in FIG. 1 includes: a plurality of upper guide plates 2 and 2a each having a square-shaped upper via-hole 1 formed therein; a plurality of lower guide plates 4 and 4a formed spaced apart from the upper guide plates 2 and 2a at arbitrary intervals in the vertical direction, and each having a square-shaped lower via-hole 3 formed therein; a typical probe whose upper part 7 and lower part 8 are respectively accommodated in the upper via-hole 1 and the lower via-hole 3, and configured to be slidably inserted into the via-holes 1 and 3 of the upper guide plates 2 and 2 a and the lower guide plates 4 and 4a so that a body 5 thereof is positioned between the upper guide plate 2a and the lower guide plate 4; and a stopper 9 protruding from one side of the outer surface of the upper part of the probe 6, and provided to prevent separation in the Z-axis direction when the probe 6 is slidably inserted into the via-holes 1 and 3 of the upper guide plates 2 and 2a and the lower guide plates 4 and 4a.

In the conventional MEMS type probe card as described above, when replacing the probe 6 after inserting the probe 6 into the via-holes 1 and 3 of the guide plates 2 and 4, if a probe head is turned 180 degrees, the probe 6 may be easily separated from the via-holes 1 and 3 in the direction of gravity. This causes a problem in that the probe 6 needs to be re-inserted into the via-holes 1 and 3.

In other words, when the separated probe 6 is re-inserted into the via-holes 1 and 3, damage to the probe 6 due to a large number of replacements and labor costs due to the work process that requires a substantial amount of replacement time may be incurred.

Moreover, the probe 6 coupled to the via-holes 1 and 3 formed through the guide plates 2 and 4 may shake, which may result in unstable operation (i.e., decreased contact stability and accuracy of the probe) and thus a deterioration in the characteristics of transmitting electrical signals.

### SUMMARY

Accordingly, the present disclosure has been made keeping in mind the above problems occurring in the related art, and the present disclosure is intended to provide a MEMS probe card with upper and lower stoppers in which a probe for examining the electrical requirements of a semiconductor device is inserted into a via-hole in a guide plate, and then the probe is prevented from being separated in the Z-axis direction by stoppers respectively formed at the top and bottom of the probe.

In addition, an objective of the present disclosure is to provide a MEMS probe card with upper and lower stoppers that prevents a probe that is coupled to a via-hole formed through a guide plate from shaking during use or movement.

In order to achieve the above objective, according to an aspect of the present disclosure, there is provided a MEMS probe card with upper and lower stoppers including: a plurality of upper guide plates each having an upper via-hole formed therein; a plurality of lower guide plates provided to be spaced apart from the plurality of upper guide plates at arbitrary intervals in a vertical direction and each having a lower via-hole formed therein; a probe whose upper part and lower part are respectively accommodated in each of the upper via-holes and the lower via-holes, and inserted into each of the upper guide plates and the lower guide plates to be liftable so that a body thereof is positioned between the each of the upper guide plates and the lower guide plates; an upper stopper protruding from a side of an outer surface of the upper part, and provided to prevent vertical separation when the probe is slidably inserted into the each of the upper via-holes of the each of the upper guide plates and the each of the lower via-holes of the each of the lower guide plates; and a lower stopper protruding from a side of the outer surface of the upper part so as to be positioned between the upper guide plates, and provided to prevent separation when the probe inserted into the each of the upper guide plates and the each of the lower guide plates is pulled in the opposite direction of insertion.

The MEMS probe card with upper and lower stoppers according to an embodiment of the present specification having the above-described configuration has the following advantages:

According to an embodiment of the present specification, after a probe for examining the electrical requirements of a semiconductor device is inserted into a via-hole in a guide plate, the probe is prevented from being separated in the Z-axis direction by stoppers respectively formed at the top and bottom of the probe, so that the work of re-inserting a separated probe into a via-hole becomes unnecessary, thereby preventing damage to the probe and labor costs resulting from work processes that require a substantial amount of replacement time.

According to an embodiment of the present specification, a probe, which is inserted into a via-hole formed through a guide plate, is prevented from shaking during use or movement, thereby ensuring the characteristic of accurately transmitting an electrical signal through stable operation.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic view of a conventional MEMS type probe card;

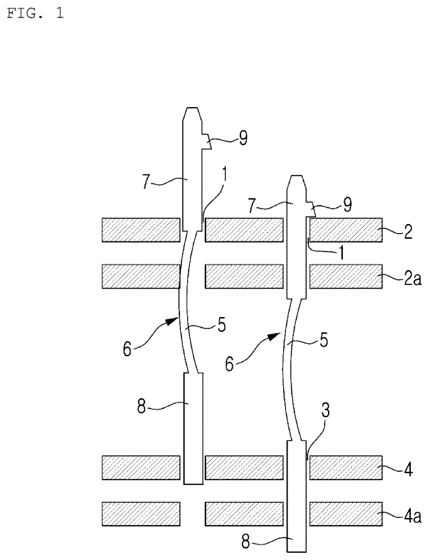

FIG. 2 is a schematic view of a MEMS type probe card with upper and lower stoppers according to a preferred embodiment of the present specification;

FIG. 3 is a view of the MEMS type probe card shown in FIG. 2;

FIG. 4 is a view of the MEMS type probe card shown in FIG. 2; and

FIG. 5 is a view of the MEMS type probe card shown in FIG. 2.

### DETAILED DESCRIPTION

Hereinafter, a MEMS probe card with upper and lower stoppers according to a preferred embodiment of the present specification will be described in detail with reference to the attached drawings.

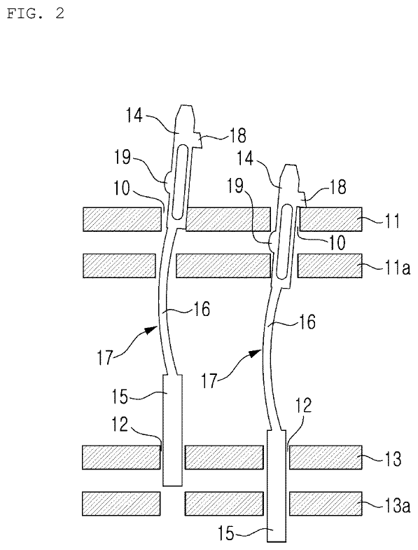

Referring to FIGS. 2 to 4, the MEMS probe card with upper and lower stoppers according to an embodiment of the present specification includes: a plurality of upper guide plates 11 each having a square-shaped upper via-hole 10 formed therein; a plurality of lower guide plates 13 formed to be spaced apart from the plurality of upper guide plates 11 at arbitrary intervals in the vertical direction and each having a square-shaped lower via-hole 12 formed therein; a typical probe 17 (as an example, nickel (Ni) or palladium (Pd) may be used, but is not meant to be limited thereto) whose upper part 14 and lower part 15 are respectively accommodated in the upper via-hole 10 and the lower via-hole 12, and configured to be slidably inserted into the upper guide plate 11 and the lower guide plate 13 so that a body 16 thereof is positioned between the upper guide plate 11 and the lower guide plate 13; an upper stopper 18 (the upper stopper 18 that is in close contact with the upper surface of the upper guide plate 11 is formed at a right angle to the upper part 14) protruding from a side of the outer surface of the upper part 14, and provided to prevent vertical separation when the probe 17 is inserted into the upper guide plate 11 and the lower guide plate 13; and a lower stopper 19 (the lower stopper 19 is formed in a hemispherical shape protruding from the upper part 14 so as to be smoothly pass through the upper via-hole 10 of the upper guide plates 11) protruding from a side of the outer surface of the upper part 14 so as to be positioned between the upper guide plates 11, and provided to prevent separation when the probe 17 inserted into the upper guide plate 11 and the lower guide plate 13 is pulled in the opposite direction of insertion.

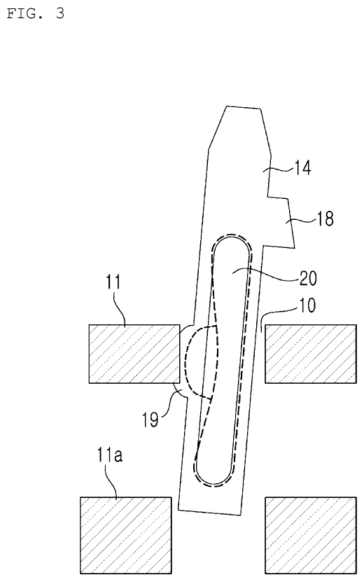

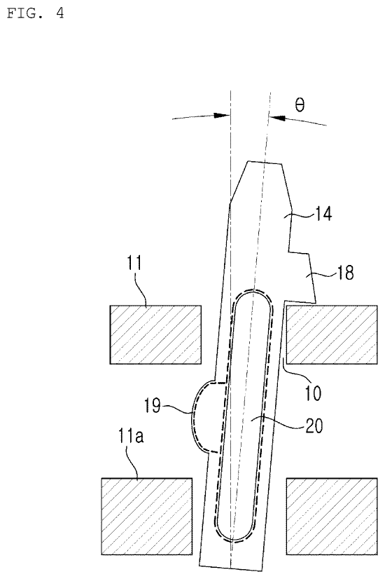

According to a more preferred embodiment, as shown in FIGS. 3 and 4, a slot 20 may be further included. The slot 20 is formed through the upper part 14 including the location where the aforementioned lower stopper 19 is provided, and is for inducing the lower stopper 19 to be elastically deformed and smoothly inserted into the upper via-hole 10 when the upper part 14 is inserted into the upper via-hole 10.

As shown in FIGS. 2 and 4, in order to increase the fixing force of the probe 17 inserted into the via-holes 10 and 12 of the upper guide plate 11 and the lower guide plate 13 mentioned above, and to prevent shaking due to vibration during use or movement of the probe 17, the upper portion of the upper part 14 is formed at an arbitrary tilt angle θ toward the upper stopper 18 with respect to the lower vertical line of the upper part 14.

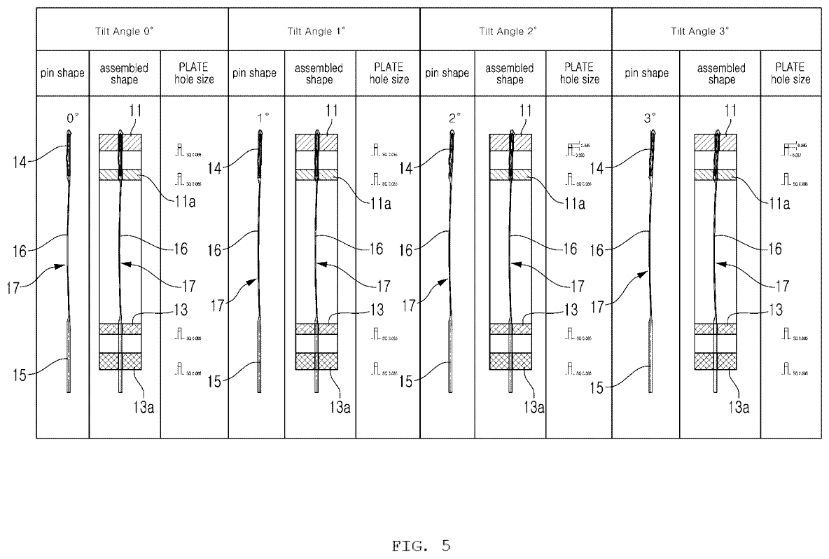

More preferably, as shown in FIGS. 2, 4, and 5, the tilt angle θ of the upper part 14 described above is within a range of 1° to 3°.

That is, in case that the tilt angle θ of the upper part 14 is 1° or less, the upper part 14 inserted into the upper via-hole 10 of the upper guide plate 11 may shake due to vibration during use or movement of the probe 17.

On the other hand, in case that the tilt angle θ of the upper part 14 is 3° or more, when the probe 17 is inserted into the upper via-hole 10 of the upper guide plate 11 and the lower via-hole 12 of the lower guide plate 13, damage may occur to the upper part 14 of the probe 17 inserted into the upper via-hole 10.

Meanwhile, the tilt angle θ of the upper part 14 described above may be variably adjusted according to the length and thickness of the upper part 14.

Hereinafter, the MEMS probe card with upper and lower stoppers according to an embodiment of the present specification is described in detail with reference to the attached drawings.

As shown in FIGS. 2 to 4, the upper stopper 18 and the lower stopper 19 are spaced apart in the vertical direction on the upper part 14 of the probe 17, and a portion of the probe 17 opposite to the upper part 14 may be slidably inserted into the upper via-hole 10 of the upper guide plates 11 and 11a and the lower via-hole 12 of the lower guide plates 13 and 13a.

To be specific, the above-mentioned lower part 15 of the probe 17 is vertically passed through the upper via-hole 10 formed through the upper guide plates 11 and 11a, and is inserted so as to be positioned in the lower via-hole 12 formed through the lower guide plates 13 and 13a.

When the upper part 14 of the probe 17 is inserted into the upper via-hole 10 formed through the upper guide plates 11 and 11a, due to the difference in the size of the inner diameter of the upper via-hole 10 and the upper part 14 including the hemispherical lower stopper 19 protruding from the outer surface thereof, the upper part 14 is compressed toward the slot 20 and elastically deformed because of the slot 20 formed through the inside of the upper part 14 (as shown in FIG. 3).

As a result, the lower stopper 19 may smoothly pass through the upper via-hole 10 of the upper guide plate 11 of the upper guide plates 11 and 11a. At this time, when the lower stopper 19 passes through the upper via-hole 10, since the upper part 14 is elastically restored, the lower stopper 19 returns to the initial position (as shown in FIG. 4). That is, the lower stopper 19 is positioned between the upper guide plates 11 and 11a.

As described above, when the lower stopper 19 passes through the upper via-hole 10 of the upper guide plates 11 and 11a, the upper stopper 18 protruding from the upper part 14 above the lower stopper 19 is inserted so as to be in a state of close contact with the upper surface of the upper guide plate 11 of the upper guide plates 11 and 11a.

In other words, as the upper part 14 and lower part 15 of the probe 17 are respectively inserted into the upper via-hole 10 of the upper guide plates 11 and 11 a and the lower via-hole 12 of the lower guide plates 13 and 13a, the body 16 of the probe 17 is positioned between the upper guide plate 11a and the lower guide plate 13.

When the upper part 14 and lower part 15 of the probe 17 are respectively inserted into the upper via-hole 10 of the upper guide plates 11 and 11 a and the lower via-hole 12 of the lower guide plates 13 and 13a, as the upper portion of the upper part 14 is formed at the arbitrary tilt angle θ toward the upper stopper 18 with respect to the lower vertical line of the upper part 14, the fixing force of the probe 17 whose upper part 14 is inserted into the upper via-hole 10 of the upper guide plate 11 is increased, thereby preventing shaking caused by vibration during use or movement of the probe 17.

Meanwhile, in the MEMS probe card with upper and lower stoppers according to an embodiment of the present specification, the probe card of the probe station, which determines whether a semiconductor device is defective, is a probe that applies an electrical signal by contacting the electrode pad of the semiconductor device, and the technical content of the probe card for testing the electrical characteristics of semiconductor devices constituting a wafer is substantially identical to the configuration commonly used in the technical field to which this specification pertains, and thus a detailed description of the configuration and function thereof is omitted.

Although the above-mentioned specification has been described with reference to exemplary preferred technical ideas, those with ordinary knowledge in the technical field to which the specification pertains will be able to make various modifications and equivalent other embodiments without departing from the essential characteristics of the specification.

In other words, the disclosed content is merely an example, and various modifications and implementations can be made by a person with ordinary knowledge in the relevant technical field without departing from the gist of the claims claimed in the claims, and thus the scope of protection of the disclosed content is not limited to the specific embodiments described above.

Therefore, the embodiments disclosed herein are not intended to limit the technical idea but to explain it, and the protection scope of the specification should be interpreted by the technical idea of the claims, and all technical ideas within the equivalent scope should be interpreted as being included in the scope of the rights of this specification.

### INDUSTRIAL APPLICABILITY

This specification can be applied to a MEMS (micro-electro mechanical system) type probe card with upper and lower stoppers, the probe card allowing probes for examining electrical requirement characteristics of semiconductor devices to be coupled to via-holes of a plurality of guide plates.

What is claimed is:

1. A MEMS-type probe card with upper and lower stoppers, the probe card comprising:
a plurality of upper guide plates each having an upper via-hole formed therein;
a plurality of lower guide plates provided to be spaced apart from the plurality of upper guide plates at arbitrary intervals in a vertical direction and each having a lower via-hole formed therein;
a probe whose upper part and lower part are respectively accommodated in each of the upper via-holes and the lower via-holes, and inserted into each of the upper guide plates and the lower guide plates to be liftable so that a body thereof is positioned between the each of the upper guide plates and the lower guide plates;
an upper stopper protruding from a side of an outer surface of the upper part, and provided to prevent vertical separation when the probe is slidably inserted into the each of the upper via-holes of the each of the upper guide plates and the each of the lower via-holes of the each of the lower guide plates; and
a lower stopper protruding from a side of the outer surface of the upper part so as to be positioned between the upper guide plates, and provided to prevent separation when the probe inserted into the each of the upper guide plates and the each of the lower guide plates is pulled in an opposite direction of insertion.

2. The MEMS-type probe card of claim 1, further comprising:
a slot formed through the upper part including a location where the lower stopper is provided, and configured to induce the lower stopper to be elastically deformed and smoothly inserted into the each of the upper via-holes when the upper part is inserted into the each of the upper via-holes.

3. The MEMS-type probe card of claim 1, wherein in order to increase a fixing force of the probe inserted into the each of the upper via-holes and the each of the lower via-holes of the each of the upper guide plates and the each of the lower guide plates to prevent shaking due to vibration during use or movement of the probe, an upper portion of the upper part is formed at an arbitrary tilt angle θ toward the upper stopper with respect to a lower vertical line of the upper part.

4. The MEMS-type probe card of claim 3, wherein the tilt angle θ is within a range of 1° to 3°.

5. The MEMS-type probe card of claim 2, wherein in order to increase a fixing force of the probe inserted into the each of the upper via-holes and the each of the lower via-holes of the each of the upper guide plates and the each of the lower guide plates to prevent shaking due to vibration during use or movement of the probe, an upper portion of the upper part is formed at an arbitrary tilt angle θ toward the upper stopper with respect to a lower vertical line of the upper part.

6. The MEMS-type probe card of claim 5, wherein the tilt angle θ is within a range of 1° to 3°.
